(19) United States
(12) Patent Application Publication
(10) Pub. No.: US 2024/0266239 A1
(43) Pub. Date: Aug. 8, 2024

(54) CHIP PACKAGE UNIT WITH OUTER PROTECTIVE LAYER AND METHOD OF MANUFACTUIRNG THE SAME

(71) Applicant: WALTON ADVANCED ENGINEERING, INC., KAOHSIUNG (TW)

(72) Inventors: HONG-CHI YU, KAOHSIUNG (TW); CHUN-JUNG LIN, KAOHSIUNG (TW); RUEI-TING GU, KAOHSIUNG (TW)

(21) Appl. No.: 18/419,576

(22) Filed: Jan. 23, 2024

(30) Foreign Application Priority Data
Feb. 2, 2023 (TW) 112103675

(51) Int. Cl. H01L 23/31; H01L 21/48; H01L 21/56; H01L 21/82; H01L 23/498

(52) U.S. Cl. CPC H01L 23/3171; H01L 21/4846; H01L 21/561; H01L 21/82; H01L 23/498

(57) ABSTRACT

A chip package unit with an outer protective layer and a method of manufacturing the same are provided. The chip package unit includes a rectangular die and at least one outer protective layer. The rectangular die has four sides. The outer protective layer is disposed on a surface of the rectangular die and having four sides. The chip package unit is divided from a wafer by a sawing process along cutting channels disposed on the wafer. The outer protective layer is formed on a surface of the wafer and covering the cutting channels completely. A cutting tool is firstly cutting the outer protective layer on the wafer and then moved downward continuously to cut the respective cutting channels. Thus the sides of the outer protective layer are flush with the sides of the rectangular die to avoid damages of the sides of the rectangular die during the sawing process.

### CROSS-REFERENCE TO RELATED APPLICATIONS

This non-provisional application claims priority under 35 U.S.C. § 119(a) on Patent Application No(s). 112103675 filed in Taiwan, R.O.C. on Feb. 2, 2023, the entire contents of which are hereby incorporated by reference.

### BACKGROUND OF THE INVENTION

The present invention relates to a chip package unit, especially to a chip package unit with an outer protective layer to protect respective sides of chips from damages caused by chipping or cracking generated during a sawing process, and a method of manufacturing the chip package unit.

Refer to FIG. 11 and FIG. 12, a chip package unit 3 available now is divided from a wafer 4 by a sawing process. The wafer 4 is provided with a plurality of rectangular dies 3b arranged in an array and a plurality of sawing channels 4a able to divide the wafer 4. Each of the sawing channels 4a is disposed between the two adjacent rectangular dies 3b. In conventional techniques, at least one outer protective layer 3a is formed on a surface of the wafer 4, as shown in FIG. 12 but the conventional outer protective layer 3a is not covering the sawing channels 4a. That means an upper side of the respective sawing channels 4a of the wafer 4 is not provided with the respective outer protective layers 3a. Thus a plurality of grooves 4b is formed on the outer protective layers 3a for allowing the sawing channels 4a to be exposed. Therefore, a cutting tool (not shown in figure) for the sawing process is aligned with the sawing channels 4a for preforming the sawing process, as shown in FIG. 12. However, during the sawing process of the wafer 4 now, edges 3e of the rectangular die 3b on two sides of the sawing channel 4a (as shown in FIG. 11) are easy to have chipping or cracking while the cutting tool (such as diamond cutter) for the sawing process is just in contact with an upper surface of the wafer 4 or the sawing channel 4a in the beginning. Thus quality of the rectangular die 3b is affected (such as damages of internal circuit) and yield rate is further reduced.

In order to avoid the above problem, laser cutting technique is used to perform a preprocessing of laser cutting on the sawing channel 4a of the wafer 4. That means the initial sawing is carried out by the laser cutting technique instead of the cutting tool for the sawing process. Then the cutting tool for the sawing process is used to perform general sawing process. Thus manufacturing cost is increased.

Moreover, as shown in FIG. 11, respective sides 3c of the rectangular die 3b are not flush with respective sides 3d of the outer protective layer 3a on the chip package unit 3 so that the edges 3e of the rectangular die 3b of the chip package unit 3 are exposed, as shown in FIG. 11. Thus the edges 3e of the rectangular die 3b are easy to get damaged due to collision.

### SUMMARY OF THE INVENTION

Therefore, it is a primary object of the present invention to provide a chip package unit with an outer protective layer and a method of manufacturing the same. The chip package unit includes a rectangular die and at least one outer protective layer. The rectangular die consists of a surface and four sides. The outer protective layer is disposed on the surface of the rectangular die and provided with four sides. The chip package unit is divided from a wafer by a sawing process along a plurality of cutting channels preset on the wafer. The respective outer protective layers are formed on a surface of the wafer and covering the respective cutting channels completely. A cutting tool for the sawing process is firstly cutting the respective outer protective layers on the wafer and then moved downward continuously to cut the respective cutting channels. Thus the respective sides of the outer protective layer are flush with the respective sides of the rectangular die. Thereby the respective sides of the rectangular die are not easily damaged due to chipping or cracking during the sawing process.

In order to achieve the above object, a chip package unit with an outer protective layer according to the present invention is provided. The chip package unit includes a rectangular die and at least one outer protective layer. The rectangular die which includes a surface and four sides is divided from a wafer by a sawing process. A plurality of the rectangular dies arranged in an array and a plurality of cutting channels for dividing the wafer are formed on the wafer. Each of the cutting channels is formed between the two adjacent rectangular dies. The outer protective layer is disposed on the surface of the rectangular die and provided with four sides. The outer protective layer is divided from the wafer by the sawing process. The respective outer protective layers are formed on a surface of the wafer and covering the respective cutting channels. The respective sides of the outer protective layer are flush with the respective sides of the rectangular die. A cutting tool for the sawing process is firstly cutting the respective outer protective layers on the wafer and then moved downward continuously to cut the respective cutting channels. Thus the respective outer protective layers are cut together with the respective cutting channels of the wafer during the sawing process.

Preferably, the chip package unit further includes a redistribution layer (RDL) which is provided with at least one dielectric layer and at least one conductive circuit. The outer protective layer is further formed by the dielectric layer while the rectangular die is electrically connected with the outside by the conductive circuit.

A method of manufacturing a chip package unit with an outer protective layer includes the following steps. Step S1: providing a wafer. The wafer is provided with a plurality of rectangular dies arranged in an array and a plurality of cutting channels for dividing the wafer. Each of the cutting channels is disposed between the two adjacent rectangular dies. Step S2: forming at least one outer protective layer on a surface of the wafer. The respective outer protective layers are covering the respective cutting channels of the wafer. Step S3: performing a sawing process. The sawing process uses a cutting tool to divide the rectangular dies from the wafer by cutting along the respective cutting channels of the wafer and thus form a plurality of chip package units. During the sawing process, first the cutting tool is cutting the respective outer protective layers on the wafer and then continuously moved downward to cut the respective cutting channels of the wafer. Thereby four sides of the respective outer protective layers on the respective chip package units are flush with four sides of the rectangular die after being divided from the wafer. The respective outer protective layers on the respective chip package units are located on a surface of the rectangular die.

Preferably, in the step S2, a redistribution layer (RDL) is firstly formed on the surface of the wafer. The RDL includes at least one dielectric layer and at least one conductive circuit. Thereby the respective outer protective layers are further formed by the respective dielectric layers.

### BRIEF DESCRIPTION OF THE DRAWINGS

FIG. 1 is a side sectional view of a first embodiment according to the present invention;

FIG. 2 is a partial enlarged view of the embodiment in FIG. 3 according to the present invention;

FIG. 3 is a side sectional view of the first embodiment in a wafer according to the present invention;

FIG. 4 is a top view of a wafer of an embodiment according to the present invention;

FIG. 5 is a side sectional view of a second embodiment according to the present invention;

FIG. 6 is a side view of a section of the second embodiment in a wafer according to the present invention;

FIG. 7 is a side sectional view of a rectangular die of an embodiment according to the present invention;

FIG. 8 is a schematic drawing showing a dielectric layer disposed on the rectangular die in FIG. 7 of an embodiment according to the present invention;

FIG. 9 is a schematic drawing showing a recess of the dielectric layer in FIG. 8 being filled with metal paste to form a metal paste layer of an embodiment according to the present invention;

FIG. 10 is a schematic drawing showing a surface of the metal paste layer in FIG. 9 flush with a surface of the dielectric layer of an embodiment according to the present invention;

FIG. 11 is a side sectional view of a chip package unit available now;

FIG. 12 is a side sectional view of a chip package unit available now on a wafer.

### DETAILED DESCRIPTION OF THE PREFERRED EMBODIMENT

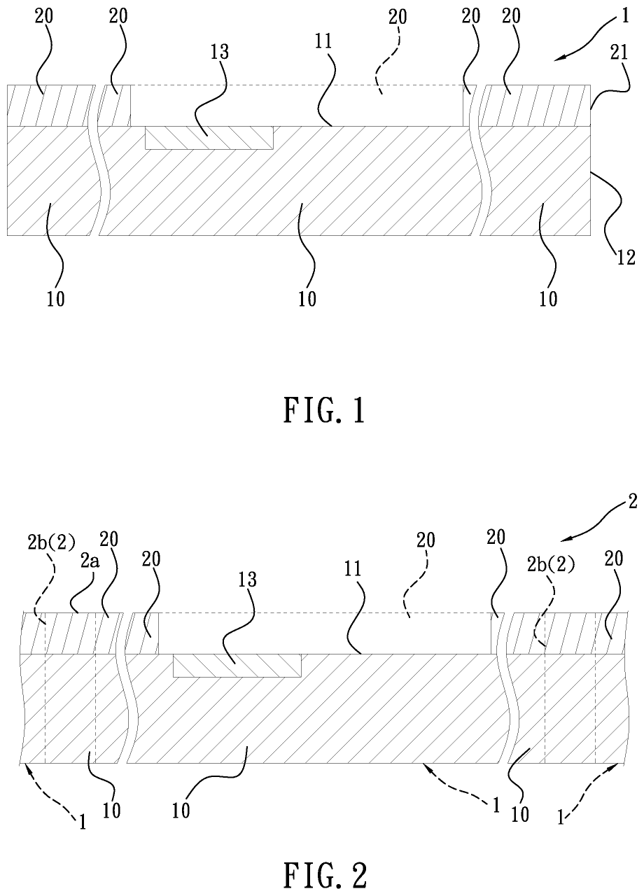

Refer to FIG. 1 and FIG. 5, a chip package unit 1 with an outer protective layer is provided. The chip package unit 1 includes a rectangular die 10 and at least one protective layer 20. The rectangular die 10 which consists of a surface 11 and four sides 12 is divided from a wafer 2 by a sawing process. A plurality of the rectangular dies 10 arranged in an array and a plurality of cutting channels 2b are formed on the wafer 2. Each of the cutting channels 2b is disposed between the two adjacent rectangular dies 10, as shown in FIG. 2-4 and FIG. 6.

According to different structures of the outer protective layer 20, the chip package unit 1 can be divided into a first embodiment (as shown in FIG. 1) and a second embodiment (as shown in FIG. 5).

As to the first embodiment shown in FIG. 1-4, the outer protective layer 20 is disposed on the surface 11 of the rectangular die 10 and is provided with four sides 21. The wafer 2 is cut by a sawing process to form the outer protective layer 20. The respective outer protective layers 20 are formed on a surface 2a of the wafer 2 and covering the respective cutting channels 2b of the wafer 2. As shown in FIG. 1 and FIG. 5, the side 21 of the outer protective layer 20 is flush with the side 12 of the rectangular die 10.

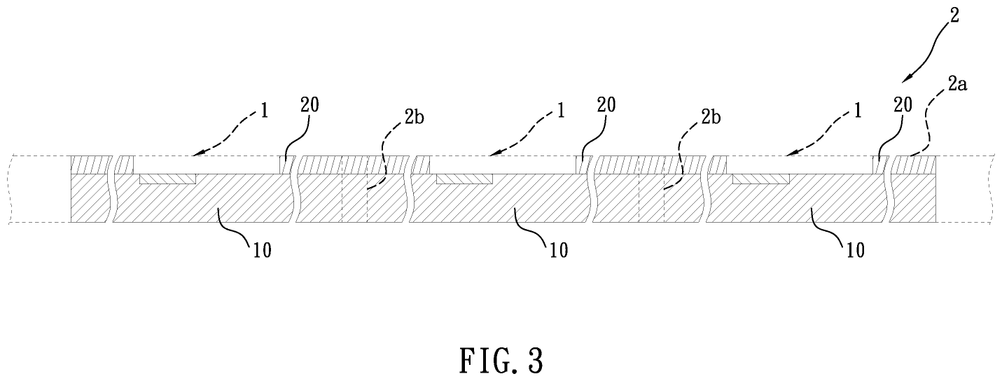

Refer to FIG. 2 and FIG. 3, a cutting tool for the sawing process is firstly cutting the respective outer protective layers 20 on the wafer 2 and then moved downward continuously to cut the respective cutting channels 2b of the wafer 2. Thus the respective outer protective layers 20 are cut together with the respective cutting channels 2b of the wafer 2 during the sawing process.

Refer to FIG. 1-4, a method of manufacturing the chip package unit 1 includes the following steps.

Step S1: providing a wafer 2. A plurality of rectangular dies 10 arranged in an array and a plurality of cutting channels 2b able to divide the wafer 2 are formed on the wafer 2. Each of the cutting channels 2b is disposed between the two adjacent rectangular dies 10.

Step S2: forming at least one outer protective layer 20 on a surface 2a of the wafer 2. The respective outer protective layers 20 are correspondingly covering the respective cutting channels 2b of the wafer 2.

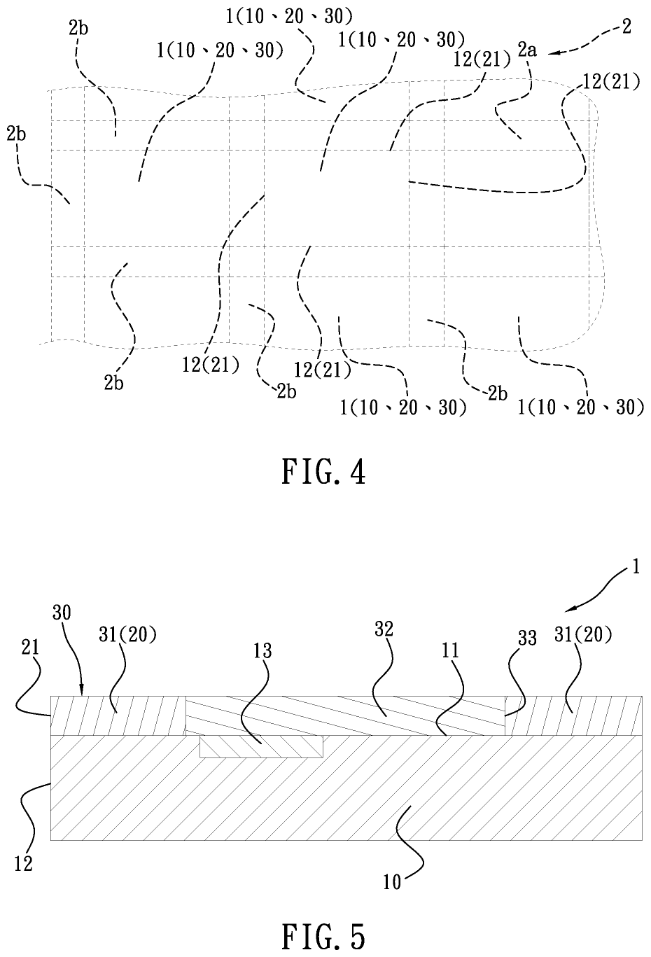

Step S3: performing a sawing process. The sawing process uses a cutting tool to divide the respective rectangular dies 10 from the wafer 2 by cutting along the respective cutting channels 2b of the wafer 2 and thus form a plurality of chip package units 1. During the sawing process, first the cutting tool is cutting the respective outer protective layers 20 on the wafer 2 and then continuously moved downward to cut the respective cutting channels 2b of the wafer 2. Thereby the four sides 21 (as shown in FIG. 4) of the respective outer protective layers 20 on the respective chip package units 1 are flush with the four sides 12 (as shown in FIG. 4) of the rectangular dies 10 after being divided from the wafer 2, as shown in FIG. 1. The respective outer protective layers 20 on the respective chip package units 1 are located on a surface 11 of the rectangular die 10, as shown in FIG. 1.

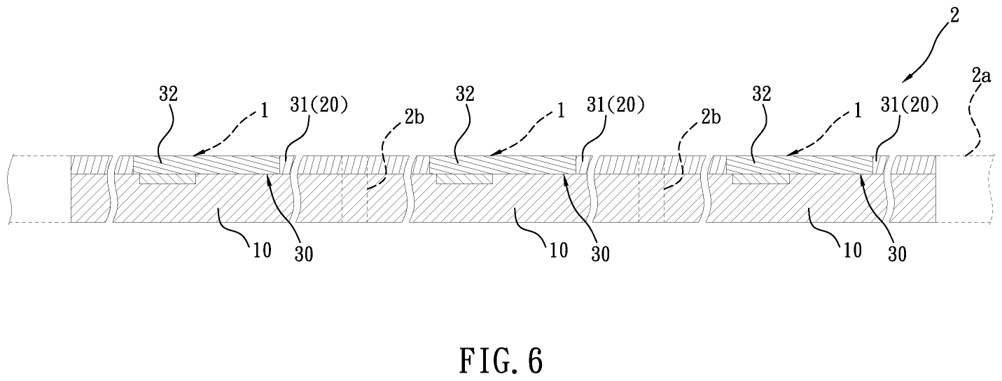

As shown in FIG. 4-6, a second embodiment is provided. As shown in FIG. 5, the respective outer protective layers 20 are disposed on the surface 11 of the rectangular die 10. The outer protective layer 20 has four sides 21, as shown in FIG. 4. The respective outer protective layers 20 are divided from the wafer 2 by the sawing process. A surface 2a of the wafer 2 is provided with the respective outer protective layers 20 which are covering the respective cutting channels 2b of the wafer 2, as shown in FIG. 6.

The chip package unit 1 further includes a redistribution layer (RDL) 30, as shown in FIG. 5. The RDL 30 is provided with at least one dielectric layer 31 and at least one conductive circuit 32. As shown in FIG. 5, the outer protective layer 20 is further formed by the dielectric layer 31. The rectangular die 10 is electrically connected with the outside by the conductive circuit 32. The rectangular die 10 further includes at least one pad 13, as show in FIG. 5. The dielectric layer 31 is covering and disposed on the surface 11 of the rectangular die 10 and provided with at least one recess 33, as show in FIG. 5. The recess 33 is for allowing the pad 13 of the rectangular die 10 to be electrically connected with the outside. The conductive circuit 32 is covering and disposed on the surface 11 of the rectangular die 10 and mounted in the recess 33, as show in FIG. 5. The pad 13 of the rectangular die 10 is electrically connected with the conductive circuit 32, as show in FIG. 5.

Refer to FIG. 6, a cutting tool for the sawing process is firstly cutting the respective dielectric layer 31 (the respective outer protective layer 20) on the wafer 2 and then moved downward continuously to cut the respective cutting channels 2b of the wafer 2. Thus the respective dielectric layers 31 (the respective outer protective layers 20) are cut together with the respective cutting channels 2b of the wafer 2 during the sawing process.

Refer to FIG. 4-6, a method of manufacturing the chip package unit 1 includes the following steps.

Step S1: providing a wafer 2. A plurality of rectangular dies 10 arranged in an array and a plurality of cutting channels 2b able to divide the wafer 2 are formed on the wafer 2. Each of the cutting channels 2b is disposed between the two adjacent rectangular dies 10.

Step S2: forming at least one redistribution layer (RDL) 30 on a surface 2a of the wafer 2, as shown in FIG. 6. The RDL 30 consists of at least one dielectric layer 31 and at least one conductive circuit 32. As shown in FIG. 5, the outer protective layer 20 is further formed by the dielectric layer 31. The respective dielectric layer 31 (the respective outer protective layers 20) are correspondingly covering the respective cutting channels 2b of the wafer 2, as shown in FIG. 6.

Step S3: performing a sawing process. Use a cutting tool to divide the rectangular dies 10 on the wafer 2 by cutting along the respective cutting channels 2b of the wafer 2 to form a plurality of the chip package units 1. During the sawing process, first the cutting tool is cutting the respective outer protective layers 20 on the wafer 2 and then continuously moved downward to cut the respective cutting channels 2b of the wafer 2, as shown in FIG. 6. Thereby the four sides 21 (as shown in FIG. 4) of the respective outer protective layers 20 on the respective chip package units 1 are flush with the four sides 12 (as shown in FIG. 4) of the rectangular die 10 after being divided from the wafer 2, as shown in FIG. 5. The respective outer protective layers 20 on the respective chip package units 1 are located on a surface 11 of the rectangular die 10, as shown in FIG. 5.

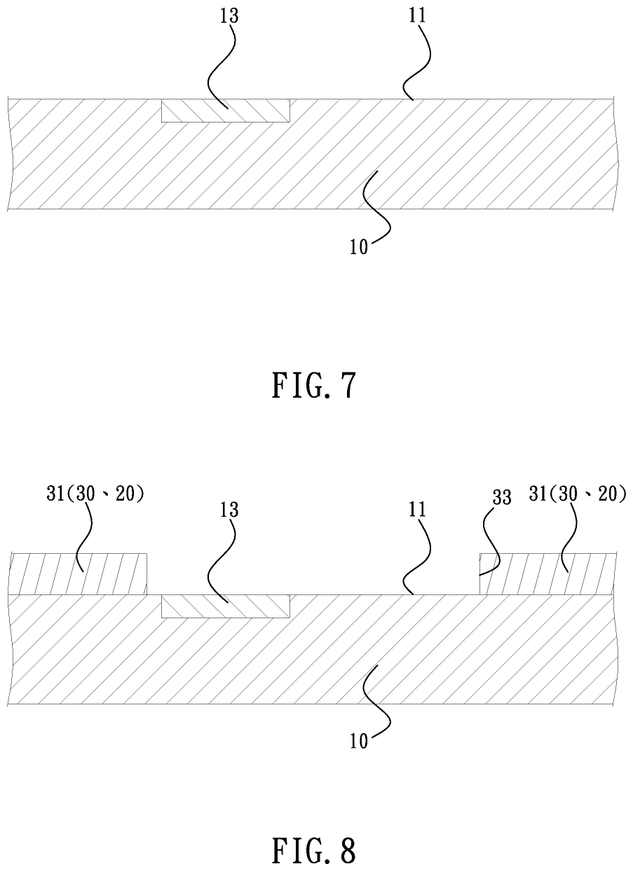

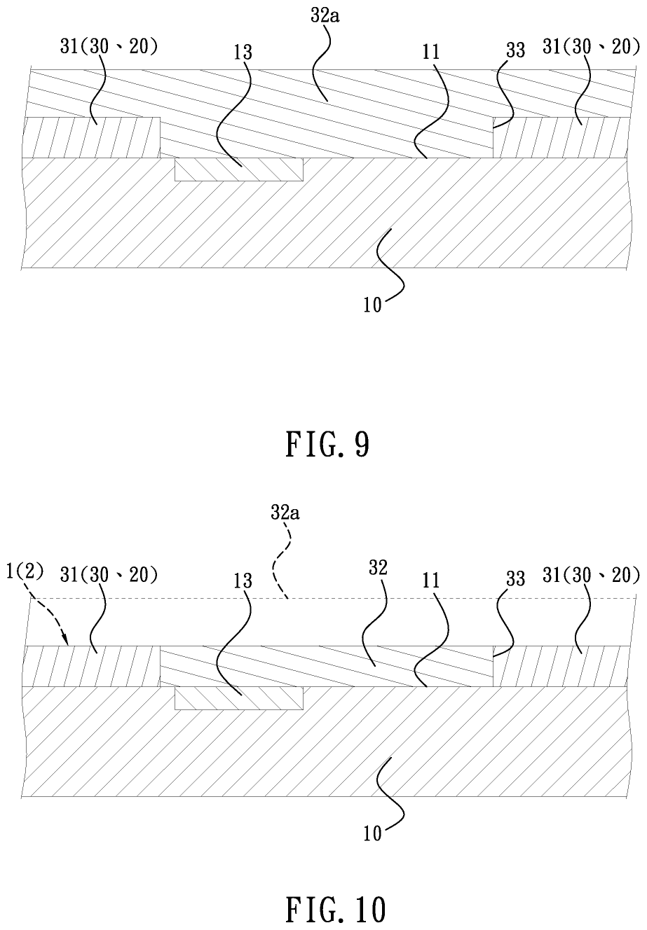

In the step S2, the surface 11 of the rectangular die 10 (as shown in FIG. 7) is covered with the respective dielectric layers 31, as shown in FIG. 8. At least one recess 33 is formed on each of the dielectric layers 31 so that at least one pad 13 is exposed through the recess 33. After formation of the recess 33, metal paste (such as silver paste or copper paste) is filled into the recess 33 to form a metal paste layer 32a whose surface is higher than surfaces of the respective dielectric layers 31, as shown in FIG. 9. After formation of the metal paste layer 32a, a part of the metal paste layer 32a whose surface higher than the surface of the respective dielectrics 31 is ground until the surfaces of the dielectric layers 31 are exposed. Thus the surface of the metal paste layer 32a is flush with the surfaces of the dielectric layers 31 to form a least one conductive circuit 32, as shown in FIG. 10. The pad 13 is electrically connected with the conductive circuit 32, as shown in FIG. 10.

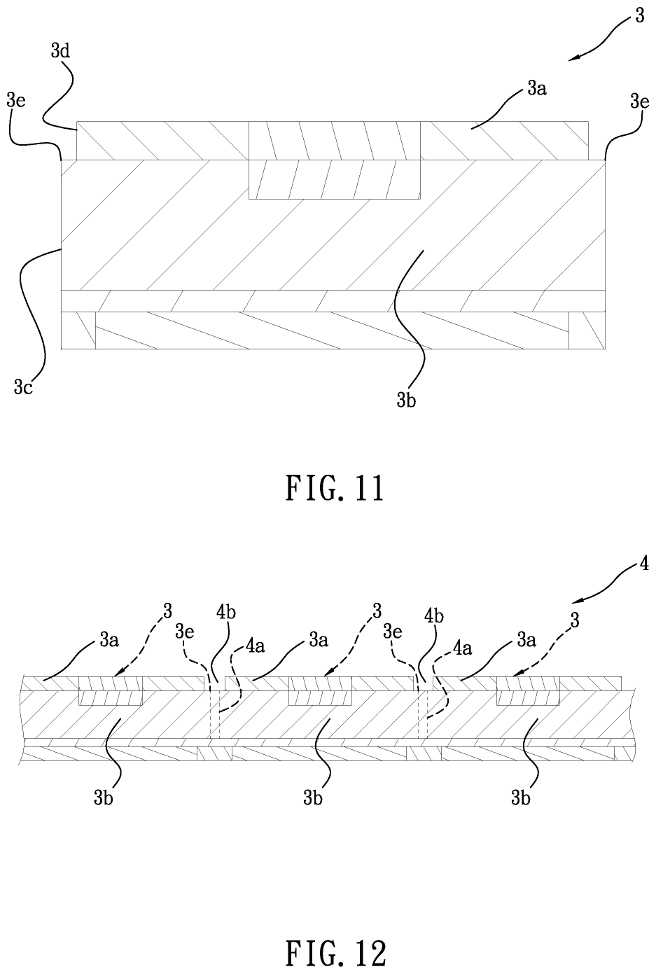

The cutting tool for the sawing process is first cutting the respective outer protective layers 20 on the wafer 2 and then continuously moved downward to cut the respective cutting channels 2b of the wafer 2. Thus the respective outer protective layers 20 are cut together with the respective cutting channels 2b of the wafer 2 during the sawing process and the chip package units 1 are divided from the wafer 2 smoothly. Therefore, the present chip package unit 1 has the following advantages compared with the chip package unit 3 available now (as shown in FIG. 11).
(1) The rectangular 10 of the chip package unit 1 according to the present invention is not easy to have chipping or cracking during the sawing process. This helps protect the rectangular 10 of the chip package unit 1 during the sawing process.
(2) During manufacturing, the chip package unit 1 can be divided from the wafer 2 smoothly without using laser technique. Thus cost at manufacturing end is saved because there is no cost and processes for using the laser cutting technique.
(3) The respective sides 21 of the respective outer protective layers 20 are flush with the respective sides 12 of the rectangular die 10. That means the respective outer protective layers 20 are covering edges of the rectangular die 10 to avoid exposure of the rectangular die 10 and provide better protection of the edges of the rectangular die 10. This helps extend the service life of the chip package unit 1.

Additional advantages and modifications will readily occur to those skilled in the art. Therefore, the invention in its broader aspects is not limited to the specific details, and representative devices shown and described herein. Accordingly, various modifications may be made without departing from the spirit or scope of the general inventive concept as defined by the appended claims and their equivalent.

1. A chip package unit with an outer protective layer comprising:
a rectangular die which includes a surface and four sides; wherein the rectangular die is divided from a wafer by a sawing process; a plurality of the rectangular dies arranged in an array and a plurality of cutting channels for dividing the wafer are both formed on the wafer while each of the cutting channels is formed between the two adjacent rectangular dies; and
at least one outer protective layer which is disposed on the surface of the rectangular die and provided with four sides; wherein the outer protective layer is divided from the wafer by the sawing process; the respective outer protective layers are formed on a surface of the wafer and covering the respective cutting channels of the wafer;
wherein the respective sides of the outer protective layer are flush with the respective sides of the rectangular die; wherein a cutting tool for the sawing process is firstly cutting the respective outer protective layers on the wafer and then moved downward continuously to cut the respective cutting channels of the wafer so that the respective outer protective layers are cut together with the respective cutting channels of the wafer during the sawing process.

2. The chip package unit as claimed in claim 1, wherein the chip package unit further includes a redistribution layer (RDL) which is provided with at least one dielectric layer and at least one conductive circuit; wherein the outer protective layer is further formed by the dielectric layer; wherein the rectangular die is electrically connected with the outside by the conductive circuit.

3. A method of manufacturing a chip package unit with an outer protective layer comprising the steps of:
Step S1: providing a wafer; wherein the wafer is provided with a plurality of rectangular dies arranged in an array and a plurality of cutting channels for dividing the wafer; each of the cutting channels is disposed between the two adjacent rectangular dies;
Step S2: forming at least one outer protective layer on a surface of the wafer; wherein the respective outer protective layers are covering the respective cutting channels of the wafer; and
Step S3: performing a sawing process in which a cutting tool is used to divide the rectangular dies from the wafer by cutting along the respective cutting channels of the wafer and thus a plurality of chip package units is formed; wherein during the sawing process, the cutting tool is first cutting the respective outer protective layers on the wafer and then continuously moved downward to cut the respective cutting channels of the wafer; thereby four sides of the respective outer protective layers on the respective chip package units are flush with four sides of the rectangular die after being divided from the wafer and the respective outer protective layers on the respective chip package units are located on a surface of the rectangular die.

4. The method as claimed in claim 3, wherein in the step S2, a redistribution layer (RDL) is firstly formed on the surface of the wafer; the RDL includes at least one dielectric layer and at least one conductive circuit; thereby the respective outer protective layers are further formed by the respective dielectric layers.
